(19) United States
(12) Patent Application Publication
(10) Pub. No.: US 2013/0340808 A1
(43) Pub. Date: Dec. 26, 2013

(54) WAVELENGTH CONVERSION TYPE SEALING MATERIAL SHEET AND SOLAR BATTERY MODULE

(71) Applicants: Masaaki Komatsu, Hitachi (JP); Choichiro Okazaki, Mito (JP); Shin Imamura, Kokubunji (JP)

(72) Inventors: Masaaki Komatsu, Hitachi (JP); Choichiro Okazaki, Mito (JP); Shin Imamura, Kokubunji (JP)

(21) Appl. No.: 13/977,276

(22) PCT Filed: Dec. 8, 2011
(86) PCT No.: PCT/JP2011/078486

§ 371 Date: Sep. 6, 2013

(30) Foreign Application Priority Data
Dec. 28, 2010 (JP) 2010 292389

(51) Int. Cl. H01L 31/055

(52) U.S. Cl. CPC H01L 31/055
USPC 136/247

(57) ABSTRACT

In order to enhance the power generation efficiency of a solar battery, the solar battery is formed to have a configuration in which a sealing material sheet formed of a sealing material having a wavelength conversion material mixed therein and having a thickness (c) is disposed between a front glass having an antireflection film and a solar battery cell; the wavelength conversion material is a needle fluorescent substance capable of converting short-wavelength light to long-wavelength light; and when a long diameter and a short diameter of the needle fluorescent substance are defined as “a” and “b”, respectively, there are relations of “a>b” and “a>c”. According to this, more outgoing light from the fluorescent substance can be directed toward the side of the solar battery cell, so that the power generation efficiency can be enhanced.

### TECHNICAL FIELD

The present invention relates to a technology of wavelength conversion film: In particular, the present invention relates to a technology of enhancing the conversion efficiency of solar batteries in which a fluorescent substance is excited upon being irradiated with near ultraviolet light to blue light and causes light emission, thereby achieving wavelength conversion.

### BACKGROUND ART

In general, the quantum efficiency of solar battery is lower in an ultraviolet light to blue light region than that in a green light to near infrared light region. Inconsequence, the efficiency of solar battery can be enhanced by wavelength-converting light having a wavelength of ultraviolet light to blue light of wavelength components of light reaching the solar battery to light of green light to near infrared light, thereby increasing the light in a wavelength region having high quantum efficiency of the solar battery. It has hitherto been known that the efficiency of solar battery is enhanced by setting up a wavelength conversion film in a route where light reaches the solar battery.

For example, in PTL 1, a fluorescent coloring agent is used as a wavelength conversion material. In addition, in PTL 2, a rare earth complex-containing ORMOSIL composite is used. In addition, in NPL 1, an organic metal complex is used. However, the above-described fluorescent coloring agent and organic metal complex are insufficient in terms of durability, and hence, they are difficult to keep a function as a wavelength conversion material for solar batteries over a long period of time. In addition, in PTL 3, a wavelength conversion material for solar batteries using a fluorescent substance is described. However, in PTL 3, specific numerical values of the efficiency enhancement amount are not described. In addition, in PTL 4, though a configuration in which monocrystalline silicon is interposed by a sealing agent having a conversion material capable of converting absorbed light into a light having a longer wavelength than that of the absorbed light is described, a specific configuration of the wavelength conversion material such as a fluorescent substance, etc. is not described. In addition, in PTL 5, it is described that a design to confine light from a light-emitting material in the inside of a solar battery by providing the light-emitting material with alignment is applied. However, PTL 5 does not describe the length of the light-emitting material, does not describe a composition of the light-emitting material, and does not describe a manufacturing method for providing the alignment.

### CITATION LIST

### Patent Literature

PTL 1: JP-A-2001-7377

PTL 2: JP-A-2000-327715

PTL 3: JP-A-2003-218379

PTL 4: JP-A-7-202243

PTL 5: JP-T-2008-536953

### Non-Patent Literature

NPL 1: Proceedings of the 58th Japan Society of Coordination Chemistry, 1PF-011

### SUMMARY OF INVENTION

### Technical Problem

For the wavelength conversion material for solar batteries, grappling with use of an organic metal complex and a fluorescent substance as an inorganic compound as a wavelength conversion material for solar batteries is made. However, in the conventional wavelength conversion materials for solar batteries, the direction of light emitted from the light-emitting material is isotropic, and therefore, there are more components of light transmitting into the side on which sunlight is incident without going toward the solar battery cell. Accordingly, the conventional wavelength conversion materials have not sufficiently enhanced the photoelectric conversion efficiency of the solar batteries yet, and hence, it is demanded to more enhance the photoelectric conversion efficiency.

Under such circumstances, the present invention has been made, and an object thereof is to provide a technology for increasing the amount of light going toward a solar battery cell among lights emitted from a wavelength conversion material, thereby enabling the photoelectric conversion efficiency of the solar batteries to be enhanced.

### Solution to Problem

Among the inventions disclosed in the present application, summaries of those which are representative are briefly described as follows. That is, a solar battery module in one embodiment of the present invention has a front glass, a transparent resin, a solar battery cell, and a back sheet. In addition, the front glass is a semi-tempered glass for solar batteries, and there may be the case where the front glass has an antireflection film.

The transparent resin is incorporated with a fluorescent substance capable of emitting visible light to near infrared light upon being excited with near ultraviolet light to blue light. In the present invention, the wavelength conversion material is either a fluorescent substance having a needle form or a needle resin having a fluorescent substance sealed therein. Since this wavelength conversion material is in a needle form, the outgoing light from the wavelength conversion material has anisotropy.

By disposing the needle fluorescent substance or the needle resin having a fluorescent substance sealed therein in a horizontal direction against the principal plane of the solar battery cell, it is possible to make the amount of light going toward the solar battery cell large. That is, by using the above-described wavelength conversion film for solar batteries, it is possible to fabricate a solar battery module having high photoelectric conversion efficiency.

### Advantageous Effect of Invention

According to the present invention, the outgoing light which has been subjected to wavelength conversion with a fluorescent substance or the like is able to make the amount of light going toward the battery cell side large, and hence, it is possible to enhance the photoelectric conversion efficiency of solar batteries.

### BRIEF DESCRIPTION OF DRAWINGS

FIG. 1 is a cross-sectional schematic view of a solar battery module in the case of mixing a wavelength conversion material in a sealing material.

FIG. 2 is a cross-sectional schematic view of a solar battery module in the case of forming a wavelength conversion layer between a sealing material and a solar battery cell.

FIG. 3 is a cross-sectional schematic view of a solar battery module in the case of mixing a wavelength conversion material in an antireflection film.

FIG. 4 is a cross-sectional schematic view of a solar battery module in the case of forming a wavelength conversion layer between an antireflection film and a front glass.

FIG. 5 is a cross-sectional schematic view of a solar battery module in the case of introducing a solar battery module into a concentrating photovoltaic.

FIG. 6 is a graph showing excitation edge wavelength dependence of a wavelength conversion material corresponding to an increase of generated electric power of a solar battery.

FIG. 7 is a graph showing particle diameter dependence of light scattering intensity.

FIG. 8 is a schematic view showing a state where a fluorescent substance is sealed in a needle resin.

### DESCRIPTION OF EMBODIMENTS

### <Structure of Solar Battery Module>

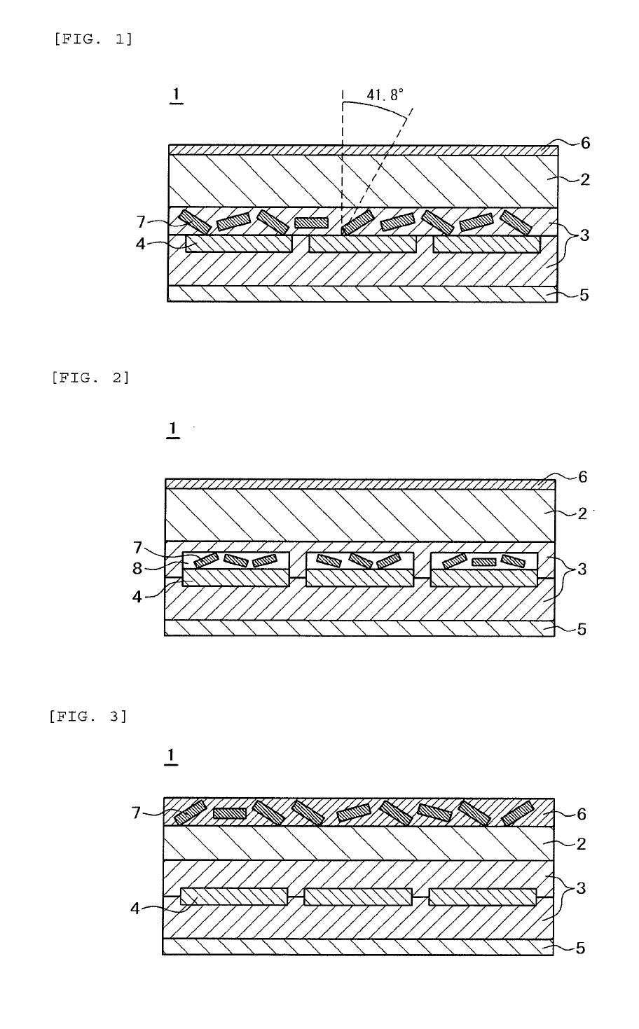

A structure of a solar battery module according to the present invention is shown in FIG. 1. A solar battery module 1 comprises a front glass 2 which is set up on the side on which sunlight is incident, a sealing material (transparent resin) 3, a solar battery cell 4, and a back sheet 5, and an antireflection film 6 is formed on the side of the front glass 2 on which sunlight is incident. Though it is desirable that the antireflection film is present, the antireflection film may be omitted. As for the component of the front glass 2, in addition to glass, any materials which do not hinder the incidence of sunlight, such as polycarbonates, acrylic resins, polyesters, polyethylene fluoride, etc., can be used so long as they are transparent.

The sealing material 3 has a role as a protective material and is disposed so as to cover the solar battery cell 4 capable of converting light energy into electric energy. In addition, as for the sealing material, in addition to EVA (ethylene-vinyl acetate copolymer), silicon potting materials, polyvinyl butyral, and the like can also be used.

As for the solar battery cell 4, a variety of solar battery cells such as monocrystalline silicon solar batteries, polycrystalline silicon solar batteries, thin film compound semiconductor solar batteries, amorphous silicon solar batteries, etc. can be used. This solar battery cell 4 is disposed singly or plurally within the solar battery module 1, and in the case where the solar battery cell 4 is disposed plurally, they are electrically connected to each other with an inter connector. As for the back sheet 5, in order to bring about weather resistance, high insulation, and strength, the back sheet 5 can contain a metal layer and a plastic film layer.

As shown in FIG. 1, a wavelength conversion material 7 can be used upon being mixed in the sealing material 3. In that case, a wavelength conversion layer in which the sealing material 3 absorbs near ultraviolet to blue light to release green to near infrared light is configured. In addition, since the solar battery module is fabricated while forming a wavelength conversion film together with the sealing material 3, the manufacturing process can be simplified.

The wavelength conversion layer is acceptable so long as it is present until at least sunlight is incident into the solar battery cell 4, and the wavelength conversion layer is acceptable so long as it is present at least either on the light-receiving surface of the front glass 2 or between the front glass 2 and the solar battery cell 4. In addition, since the wavelength conversion layer is acceptable so long as it is able to absorb only light which is incident into the solar battery cell, the wavelength conversion layer may exist at a position at which the converted light can be supplied into at least an incident part of sunlight into the solar battery cell 4, and it may not exist uniformly in the same area as the surface area of the solar battery module 1.

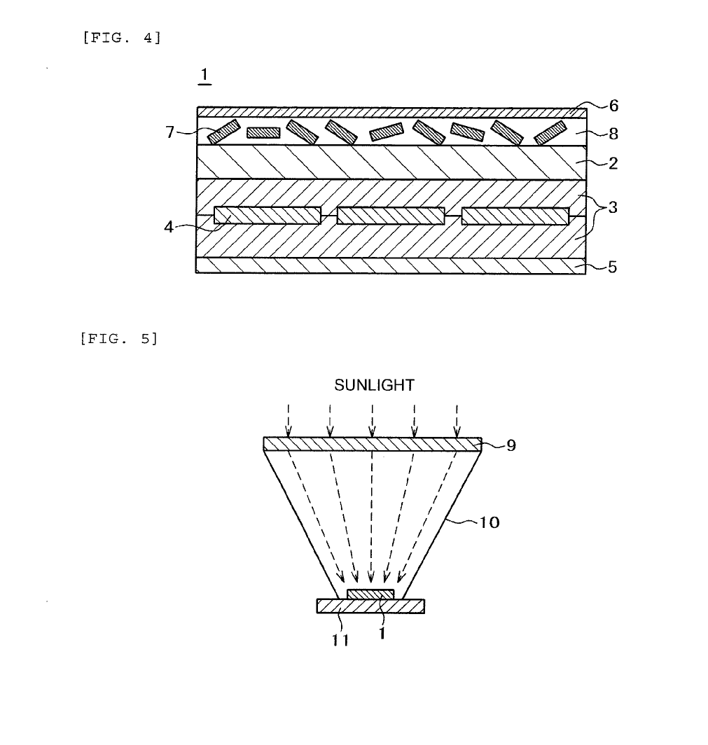

In consequence, as for the structure of the solar battery module, in addition to the configuration shown in FIG. 1, a wavelength conversion layer 8 can be formed on the solar battery cell side of the sealing material 3 as shown in FIG. 2. In that case, a distance of the light released from the wavelength conversion material to the solar battery cell is short, and the diffusion of light can be suppressed. In addition, as shown in FIG. 3, in the case of providing the antireflection film 6, the wavelength conversion material 7 can be used upon being kneaded in the antireflection film 6. In that case, since the wavelength conversion film is fabricated together with the antireflection film 6, the manufacturing process can be simplified. In addition, since the wavelength conversion film is formed on the surface of the front glass in which the absorption of ultraviolet light by the front glass 2 does not occur, it is possible to achieve the wavelength conversion of much more ultraviolet light into visible light to near infrared light.

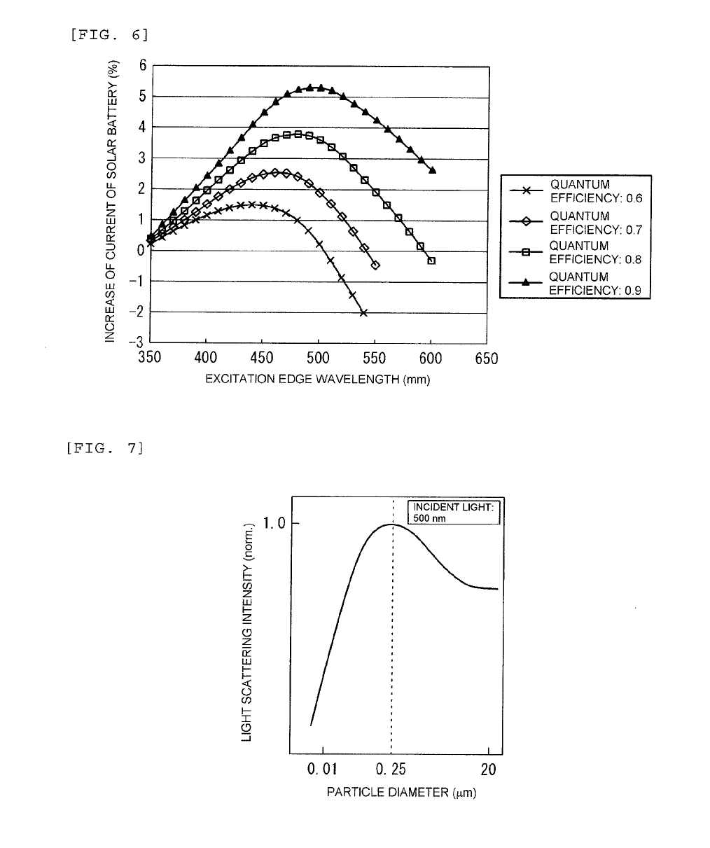

As shown in FIG. 4, the wavelength conversion film 8 having the wavelength conversion material 7 can be formed between the antireflection film 6 and the front glass 2. In that case, since the wavelength conversion film 8 is formed on the surface in which the absorption of ultraviolet light by the front glass 2 does not occur, it is possible to achieve the wavelength conversion of much more ultraviolet light into visible light to near infrared light. In addition, as shown in FIG. 5, the above-described configuration can also be used as a concentrating photovoltaic by using a condensing lens 9, a supporting frame 10, a substrate 11, and the like. Since short-wavelength light having high energy is converted into long-wavelength light having low energy by the wavelength conversion material, and excessive energy of a band gap or more of the solar battery cell is reduced, even when used as a concentrating photovoltaic, a temperature increase of the solar battery cell can be suppressed.

In the light of above, as for the solar battery having a structure in which a material containing a fluorescent substance is set up in a route where light reaches the solar battery, there may be considered a method of mixing the material containing a fluorescent substance in the material of the front glass 2 or the sealing material 3; a method of blending the wavelength conversion material 7 in an appropriate solvent and coating the solution on a desired place; and the like. All of these methods may be adopted so long as the absorption of sunlight in the solar battery cell 4 is not hindered, and the function of the wavelength conversion material 7 is not impaired. Above all, the method of using the wavelength conversion material 7 shown in FIG. 1 upon being kneaded in the sealing material 3 is able to simplify the manufacturing method and is excellent as a method of setting up the wavelength conversion material 7.

### <Wavelength Conversion Film Using Anisotropic Light-Emitting Material>

In the case of using a fluorescent substance material as the wavelength conversion material, when the fluorescent substance is spherical, the light emission from the fluorescent substance is isotropic, and components of light transmitting into the side on which sunlight is incident without going toward the solar battery cell are produced. As shown in FIG. 1, light at an angle lower than 41.8° (sin⁻¹(1/1.5)=41.8°) from the vertical line to the solar battery cell 4 transmits into the side on which sunlight is incident due to a relation of refractive index and does not contribute to the power generation of the solar battery. A proportion of the component of light which does not contribute to this power generation is about 13% of light emitted from the fluorescent substance 7. Incidentally, in the present description, the wavelength conversion material 7 is sometimes referred to as a light-emitting material.

In FIG. 1, “41.8°” is an angle at which among lights outgoing from the wavelength conversion material 7, light going toward the opposite side to the solar battery cell 4 does not cause total reflection at an interface with air. Namely, when the light outgoing from the wavelength conversion material 7 causes total reflection at the interface, it again goes toward the direction of the solar battery cell 4, whereas when the light outgoing from the wavelength conversion material 7 does not cause total reflection, it outgoes upwardly in FIG. 1 and does not contribute to the power generation.

The needle fluorescent substance or the wavelength conversion material having a fluorescent substance sealed in a needle resin can bring about directional properties of the light emission. That is, in the case where the shape of the wavelength conversion material is vertically oriented, a proportion of the component of light going toward the vertical direction is larger than a proportion of the component of light going toward the horizontal direction. This is because the refractive index of the inorganic fluorescent substance is from about 1.5 to 2.0, a value of which is larger than the refractive index (1.5) of the sealing material. FIG. 8 shows an example in which the fluorescent substance is sealed in the needle resin.

In consequence, the vertically oriented fluorescent substance material or wavelength conversion material having a fluorescent substance sealed in a needle resin is arranged at an angle higher than 41.8°, namely the major axis of the wavelength conversion material is made coincident with the parallel direction to the surface on which sunlight is incident. According to this, in the light produced from the light-emitting material, a proportion of the component of light which does not go toward the solar battery cell can be significantly reduced.

Here, when the vertical length of the needle fluorescent substance or the light-emitting material having a fluorescent substance sealed in a needle resin, namely the long diameter, is defined as “a”, and the horizontal length, namely the short diameter, is defined as “b”, there is a relation of “a>b”; and when the thickness of the wavelength conversion film is defined as “c”, a relation of “a>c” is preferable. In order to set up the needle fluorescent substance and the light-emitting material having a fluorescent substance sealed in a needle resin at an angle higher than 41.8°, the relation is set up at “a>1.34c”. Incidentally, a ratio of the long diameter (a) of the needle fluorescent substance or the light-emitting material having a fluorescent substance sealed in a needle resin to the short diameter (b) thereof is more preferably “a>2b”.

By adopting such a configuration, the raw material of the sealing material and the needle fluorescent substance or the light-emitting material having a fluorescent substance sealed in a needle resin are kneaded and molded into a film form, whereby a wavelength conversion film having the light-emitting material mixed therein can be easily manufactured at a desired angle. In that case, the light-emitting material is randomly set up in the sealing material at an angle of from 41.8° to 90°.

In addition, the wavelength conversion film in which the needle fluorescent substance or the light-emitting material having a fluorescent substance sealed in a needle resin is mixed may be a single layer, or can be formed so as to have a multilayered structure upon being superimposed. When a multilayered structure is formed, even in the case where the long diameter (a) of the needle fluorescent substance and the light-emitting material having a fluorescent substance sealed in a needle resin is short, the thickness for protecting the solar battery cell can be ensured without impairing the function of the sealing material by making the thickness of a single layer of the wavelength conversion film thin and superimposing those wavelength conversion films to form a multilayered structure. In addition, as for the needle resin for sealing the fluorescent substance therein, though polymers of an acrylic acid ester or a methacrylic acid ester are preferable, transparent materials such as a silicon resin, a glass, etc. are acceptable so long as they do not impair the function of wavelength convention.

The long diameter (a) or short diameter (b) of the needle fluorescent substance or the needle resin having a fluorescent substance sealed therein as described above is a diameter in the case of applying a statistical treatment as described later because it varies depending upon the individual particle.

### <Excitation Edge Wavelength, Particle Diameter, and Addition Concentration as Wavelength Conversion Material>

In general, the quantum efficiency of solar battery becomes low as the light is turned from blue light to near ultraviolet light, and the wavelength of the incident light becomes shorter. On the other hand, a material in which the quantum efficient of a fluorescent substance is from about 0.7 to 0.9 is used as the wavelength conversion material. Results obtained by making a trial calculation of an increase of generated electric power in the case of changing the excitation edge wavelength on the long wavelength side of a fluorescent substance having an excitation band at 300 nm or more where a spectral intensity of sunlight is present are shown in FIG. 6. Here, the excitation edge wavelength means a wavelength at which the excitation intensity on the long wavelength side of the excitation spectrum rises up and is defined to show a wavelength at which a peak intensity of the excitation spectrum is 10%.

When the quantum efficiency is from 0.6 to 0.9, the increase of generated electric power by the wavelength conversion is seen at an excitation edge wavelength of from 350 to 670 nm. When the excitation edge wavelength is from 430 to 500 nm, the increase of generated electric power is the largest. That is, so long as the quantum efficiency of the wavelength conversion material is from 0.6 to 0.9, by using a wavelength conversion material having an excitation edge wavelength falling within the range of from 430 to 500 nm, the generated electric power of solar battery can be enhanced at a maximum. When the quantum efficiency is from 0.7 to 0.9, by using the wavelength conversion material having the excitation edge wavelength falling within the range of from 450 to 500 nm, the generated electric power of solar battery can be enhanced at a maximum. In addition, in the case where the quantum efficiency of the wavelength conversion material is 0.7 or more, even when a material further having an excitation edge wavelength of from 410 to 600 nm is used, the generated electric power of solar battery can be enhanced as compared with the case of wavelength conversion using a conventional organic complex (quantum efficiency: about 0.6).

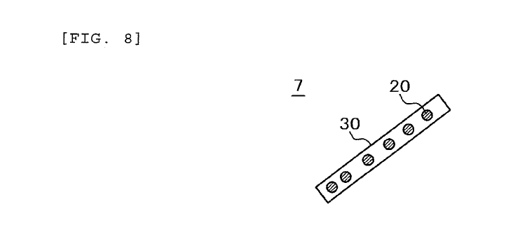

On the other hand, in the fluorescent substance, there is also a loss due to optical scattering, and its degree is related to the particle diameter and the addition concentration. As for the relation between the particle diameter of the wavelength conversion material and the light scattering intensity, when the wavelength of sunlight is 500 nm, the light scattering intensity becomes maximum at a particle diameter of 250 nm, a value of which is a half of the wavelength of sunlight, due to the Mie scattering. The relation between light scattering intensity and particle diameter is shown in FIG. 7. When the particle diameter is smaller than 250 nm, the scattering intensity is dominated by the Rayleigh scattering, and the smaller the particle diameter, the more reduced the scattering intensity is; whereas when the particle diameter is larger than 250 nm, the scattering intensity is dominated by the geometric optical scattering, and the larger the particle diameter, the more lowered the light scattering intensity is. When the particle diameter is small, though the light scattering intensity is lowered, the light emission intensity of the fluorescent substance is lowered, whereas when the particle diameter is excessively large, it is necessary to increase the addition concentration, and the function of the sealing material is impaired. Therefore, the particle diameter is suitably in the range of from 10 nm to 20 μm. Though this range includes the particle diameter of 250 nm, which is a scattering peak due to the Mie scattering, it is a value set up taking the light emission efficiency of fluorescent substance into consideration.

Next, as for the addition concentration of the wavelength conversion material into the sealing material, it is desirable that at least one fluorescent substance particle is present on the side on which sunlight is incident, and the fluorescent substance mixed in the sealing material evenly gets the sunlight. When the addition concentration is in excess, the optical scattering increases, whereas when the addition concentration is too low, the light passing therethrough without being subjected to wavelength conversion increases. Accordingly, in the case of a fluorescent substance having an average particle diameter of 2.3 μm, the addition concentration is 2% by weight. In addition, in the case of a fluorescent substance having an average particle diameter of 5.8 μm, the addition concentration is 5% by weight. In addition, in the case of a fluorescent substance having an average particle diameter of 1.2 μm, the addition concentration is 1% by weight. In consequence, in the case where the average particle diameter of the fluorescent substance is from 1 to 5 μm, the addition concentration is from 1 to 5% by weight. However, such a value is a result obtained by calculating the necessary amount of the fluorescent substance, and an optimum concentration is present around this amount.

In consequence, when an average particle diameter of the fluorescent substance is defined as A (μm), as for an optimum concentration range B (% by weight), the effect starts to become apparent at about 1/200 times of the optimum concentration 2A/2.3, and the effect is found until about 10 times. In consequence, the concentration of the fluorescent substance is favorably in the range of (0.004A≦B≦8.7A), and when stopping of light and light scattering are taken into consideration, more preferably, the effect of the wavelength conversion is high in the range of from about 1/100 times to about 5 times of the optimum concentration 2A/2.3. In consequence, it may be considered that the concentration of the fluorescent substance is optimum in the range of (0.008A≦B≦4.3A).

### <Wavelength Conversion Material>

As for the wavelength conversion material, a material capable of converting near ultraviolet light to blue light of not more than 500 nm into green light to near infrared light of from 500 nm to 1,100 nm and making the converted light incident into the solar battery cell is preferable. In particular, a material having an excitation band at 300 nm or more where a spectral intensity of sunlight is present, a quantum efficiency of 0.7 or more, and an excitation edge wavelength of from 410 to 600 nm is preferable. A material having an excitation edge wavelength of from 430 to 500 nm is the most preferable. Furthermore, from the standpoints of luminance lifetime and moisture resistance, an inorganic fluorescent substance material which is used for a variety of displays, lamps, and white LED, and the like is preferable. However, the material is limited to one whose excitation band is distributed in near ultraviolet light to blue light.

From these viewpoints, in the present invention, a fluorescent substance material composition having an excitation band in near ultraviolet light to blue light and having high light conversion efficiency was chosen. Examples of such a fluorescent substance include a fluorescent substance represented by MMgAl₁₀O₁₇:Eu,Mn, wherein M is one kind or a plural kind of elements of Ba, Sr, and Ca; a fluorescent substance whose parent material contains any one of (Ba, Sr)₂SiO₄ (Ba, Sr, Ca)₂SiO₄, Ba₂SiO₄, Sr₃SiO₅, (Sr, Ca, Ba)₃SiO₅, (Ba, Sr, Ca)₃MgSi₂O₈, Ca₃Si₂O₇, Ca₂ZnSi₂O₇, Ba₃Sc₂Si₃O₁₂, and Ca₃Sc₂Si₃O₁₂; and a fluorescent substance whose parent material is represented by MAlSiN₃, wherein M is any one kind or a plural kind of elements of Ba, Sr, Ca, and Mg. In addition, a rare earth element such as Eu, Ce, etc. is used as a light-emitting central element.

In addition, an average particle diameter of the fluorescent substance which is used in the present invention is from 10 nm to 20 μm. Here, the average particle diameter of the fluorescent substance can be specified as follows. Examples of a method of examining the average particle diameter of the particle (fluorescent substance particle) include a method of the measurement with a particle size distribution analyzer; a method of the direct observation with an electron microscope; and the like. When the case of examining the average particle diameter with an electron microscope is taken as an example, the average particle diameter can be calculated as follows. Each of sections of variables of the particle diameter of the particle ( . . . , 0.8 to 1.2 μm, 1.3 to 1.7 μm, 1.8 to 2.2 μm, . . . , 6.8 to 7.2 μm, 7.3 to 7.7 μm, 7.8 to 8.2 μm, . . . , etc.) is expressed by a class value ( . . . , 1.0 μm, 1.5 μm, 2.0 μm, . . . , 7.0 μm, 7.5 μm, 8.0 μm, . . . , etc.), and this is defined as xᵢ. Then, when the frequency of each of the variables observed by an electron microscope is expressed by fᵢ, an average value A is expressed as follows.

A=Σxᵢfᵢ/Σfᵢ=Σxᵢfᵢ/N

However, Σfᵢ=N. In the fluorescent substance of the present invention, since the excitation edge wavelength is adaptive as a wavelength conversion material, an excellent effect as a wavelength conversion material for solar batteries can be obtained.

In the case where the fluorescent substance is in a needle form having a long diameter (a) and a short diameter (b), an average particle diameter obtained by the above-described measurement is adopted with respect to each of the long diameter (a) and the short diameter (b). Namely, in the present description, the long diameter (a) refers to an average long diameter (a), and the short diameter (b) refers to an average short diameter (b). Then, when the particle diameter of the needle fluorescent substance is referred to, it means “(a+b)/2”. The long diameter (a) or the short diameter (b) in the needle resin having a fluorescent substance sealed therein is a value obtained by performing the same statistical treatment. Namely, in the present description, the long diameter (a) of the needle resin having a fluorescent substance sealed therein refers to an average long diameter (a), and the short diameter (b) refers to an average short diameter (b).

### <Fabrication of Wavelength Conversion Type Sealing Material Sheet and Solar Battery Module>

A variety of solar battery modules using the foregoing wavelength conversion material were fabricated. Examples thereof are hereunder described.

### EXAMPLE 1

To a transparent resin (EVA), small amounts of an organic peroxide, a crosslinking auxiliary, and an adhesion enhancer were added; a needle acrylic resin (vertical length a=680 μm, horizontal length b=20 μm) having a (Ba,Ca,Sr)MgAl₁₀O₁₇:Eu,Mn fluorescent substance (particle diameter: 6 μm) sealed therein was mixed in a proportion of 0.5% by weight; the contents were kneaded using a roll mill heated at 80° C.; and the kneaded material was then interposed between two sheets of polyethylene terephthalate using a press, thereby fabricating a sealing material 3 composed mainly of EVA and having a thickness of 500 μm. In addition, as for the above-described fluorescent substance composition, one kind composition or a mixture of plural kinds of compositions may be used.

Subsequently, this sealing material 3 was allowed to stand for cooling to room temperature; the polyethylene terephthalate film was released; the resultant was laminated together with a front glass 2, a solar battery cell 4, and a back sheet 5 as shown in FIG. 1; and the laminate was preliminarily press bonded using a vacuum laminator set up at 150° C. The preliminarily press bonded laminate was heated in an oven at 155° C. for 30 minutes and then subjected to crosslinking and adhesion, thereby fabricating a solar battery panel 1. In the present invention, the fluorescent substance whose excitation band is adaptive is used as the wavelength conversion material, the wavelength conversion material having high light conversion efficiency is further used, and the wavelength conversion material is further set up in the direction where the amount of light going toward the solar battery cell is increased. Therefore, the current amount of the solar battery panel was large, and the current amount was increased by 10% as compared with the case of not using the wavelength conversion material.

### EXAMPLE 2

To a transparent resin (EVA), small amounts of an organic peroxide, a crosslinking auxiliary, and an adhesion enhancer were added; a needle acrylic resin (vertical length a=200 μm, horizontal length b=20 μm) having a (Ba,Ca,Sr)MgAl₁₀O₁₇:Eu,Mn fluorescent substance (particle diameter: 50 μm) sealed therein was mixed in a proportion of 1% by weight; the contents were kneaded using a roll mill heated at 80° C.; and the kneaded material was then interposed between two sheets of polyethylene terephthalate using a press, thereby fabricating a sealing material 3 composed mainly of EVA and having a thickness of 166 μm. In addition, as for the above-described fluorescent substance composition, one kind composition or a mixture of plural kinds of compositions may be used.

Subsequently, this sealing material 3 was allowed to stand for cooling to room temperature; the polyethylene terephthalate film was released; three sheets of the sealing material 3 were superimposed together with a front glass 2, a solar battery cell 4, and a back sheet 5 to form a multilayered structure and laminated as shown in FIG. 1; and the laminate was preliminarily press bonded using a vacuum laminator set up at 150° C. The preliminarily press bonded laminate was heated in an oven at 155° C. for 30 minutes and then subjected to crosslinking and adhesion, thereby fabricating a solar battery panel 1. In the present invention, the fluorescent substance whose excitation band is adaptive is used as the wavelength conversion material, the wavelength conversion material having high light conversion efficiency is further used, and the wavelength conversion material is further set up in the direction where the amount of light going toward the solar battery cell is increased. Therefore, the current amount of the solar battery panel was large, and the current amount was increased by 9% as compared with the case of not using the wavelength conversion material.

### EXAMPLE 3

To a transparent resin (EVA), small amounts of an organic peroxide, a crosslinking auxiliary, and an adhesion enhancer were added; a (Ba, Ca, Sr)MgAl₁₀O₁₇:Eu, Mn fluorescent substance (vertical length: 60 μm, horizontal length: 5 μm) was mixed in a proportion of 0.5% by weight; the contents were kneaded using a roll mill heated at 80° C.; and the kneaded material was then interposed between two sheets of polyethylene terephthalate using a press, thereby fabricating a sealing material 3 composed mainly of EVA and having a thickness of 50 μm. In addition, as for the above-described fluorescent substance composition, one kind composition or a mixture of plural kinds of compositions may be used.

Subsequently, this sealing material 3 was allowed to stand for cooling to room temperature; the polyethylene terephthalate film was released; ten sheets of the sealing material 3 were superimposed together with a front glass 2, a solar battery cell 4, and a back sheet 5 to form a multilayered structure and laminated as shown in FIG. 1; and the laminate was preliminarily press bonded using a vacuum laminator set up at 150° C. The preliminarily press bonded laminate was heated in an oven at 155° C. for 30 minutes and then subjected to crosslinking and adhesion, thereby fabricating a solar battery panel 1. In the present invention, the fluorescent substance whose excitation band is adaptive is used as the wavelength conversion material, the wavelength conversion material having high light conversion efficiency is further used, and the wavelength conversion material is further set up in the direction where the amount of light going toward the solar battery cell is increased. Therefore, the current amount of the solar battery panel was large, and the current amount was increased by 12% as compared with the case of not using the wavelength conversion material.

### EXAMPLE 4

To a transparent resin (EVA), small amounts of an organic peroxide, a crosslinking auxiliary, and an adhesion enhancer were added; a (Ba,Sr)₂SiO₄:Eu fluorescent substance (vertical length: 60 μm, horizontal length: 5 μm) was mixed in a proportion of 0.5% by weight; the contents were kneaded using a roll mill heated at 80° C.; and the kneaded material was then interposed between two sheets of polyethylene terephthalate using a press, thereby fabricating a sealing material 3 composed mainly of EVA and having a thickness of 50 μm. In addition, as for the above-described fluorescent substance composition, one kind composition or a mixture of plural kinds of compositions may be used.

Subsequently, this sealing material 3 was allowed to stand for cooling to room temperature; the polyethylene terephthalate film was released; ten sheets of the sealing material 3 were superimposed together with a front glass 2, a solar battery cell 4, and a back sheet 5 to form a multilayered structure and laminated as shown in FIG. 1; and the laminate was preliminarily press bonded using a vacuum laminator set up at 150° C. The preliminarily press bonded laminate was heated in an oven at 155° C. for 30 minutes and then subjected to crosslinking and adhesion, thereby fabricating a solar battery panel 1. In the present invention, the fluorescent substance whose excitation band is adaptive is used as the wavelength conversion material, the wavelength conversion material having high light conversion efficiency is further used, and the wavelength conversion material is further set up in the direction where the amount of light going toward the solar battery cell is increased. Therefore, the current amount of the solar battery panel was large, and the current amount was increased by 10% as compared with the case of not using the wavelength conversion material.

### EXAMPLE 5

To a transparent resin (EVA), small amounts of an organic peroxide, a crosslinking auxiliary, and an adhesion enhancer were added; a (Ba,Sr,Ca)₂SiO₄:Eu fluorescent substance (vertical length: 60 μm, horizontal length: 5 μm) was mixed in a proportion of 0.5% by weight; the contents were kneaded using a roll mill heated at 80° C.; and the kneaded material was then interposed between two sheets of polyethylene terephthalate using a press, thereby fabricating a sealing material 3 composed mainly of EVA and having a thickness of 50 μm. In addition, as for the above-described fluorescent substance composition, one kind composition or a mixture of plural kinds of compositions may be used.

Subsequently, this sealing material 3 was allowed to stand for cooling to room temperature; the polyethylene terephthalate film was released; ten sheets of the sealing material 3 were superimposed together with a front glass 2, a solar battery cell 4, and a back sheet 5 to form a multilayered structure and laminated as shown in FIG. 1; and the laminate was preliminarily press bonded using a vacuum laminator set up at 150° C. The preliminarily press bonded laminate was heated in an oven at 155° C. for 30 minutes and then subjected to crosslinking and adhesion, thereby fabricating a solar battery panel 1. In the present invention, the fluorescent substance whose excitation band is adaptive is used as the wavelength conversion material, the wavelength conversion material having high light conversion efficiency is further used, and the wavelength conversion material is further set up in the direction where the amount of light going toward the solar battery cell is increased. Therefore, the current amount of the solar battery panel was large, and the current amount was increased by 11% as compared with the case of not using the wavelength conversion material.

### EXAMPLE 6

To a transparent resin (EVA), small amounts of an organic peroxide, a crosslinking auxiliary, and an adhesion enhancer were added; a CaAlSiN₃:Eu fluorescent substance (vertical length: 60 μm, horizontal length: 5 μm) was mixed in a proportion of 0.5 by weight; the contents were kneaded using a roll mill heated at 80° C.; and the kneaded material was then interposed between two sheets of polyethylene terephthalate using a press, thereby fabricating a sealing material 3 composed mainly of EVA and having a thickness of 50 μm. In addition, as for the above-described fluorescent substance composition, one kind composition or a mixture of plural kinds of compositions may be used.

Subsequently, this sealing material 3 was allowed to stand for cooling to room temperature; the polyethylene terephthalate film was released; ten sheets of the sealing material 3 were superimposed together with a front glass 2, a solar battery cell 4, and a back sheet 5 to form a multilayered structure and laminated as shown in FIG. 1; and the laminate was preliminarily press bonded using a vacuum laminator set up at 150° C. The preliminarily press bonded laminate was heated in an oven at 155° C. for 30 minutes and then subjected to crosslinking and adhesion, thereby fabricating a solar battery panel 1. In the present invention, the fluorescent substance whose excitation band is adaptive is used as the wavelength conversion material, the wavelength conversion material having high light conversion efficiency is further used, and the wavelength conversion material is further set up in the direction where the amount of light going toward the solar battery cell is increased. Therefore, the current amount of the solar battery panel was large, and the current amount was increased by 8% as compared with the case of not using the wavelength conversion material.

### EXAMPLE 7

Subsequently, a solar battery module was fabricated using the above-described wavelength conversion material. To a transparent resin (EVA), small amounts of an organic peroxide, a crosslinking auxiliary, and an adhesion enhancer were added; a needle acrylic resin (vertical length a=680 μm, horizontal length b=20 μm) having a (Ba, Sr)₂SiO₄:Eu fluorescent substance (particle diameter: 10 μm) sealed therein was mixed in a proportion of 0.5% by weight; and the contents were kneaded using a roll mill heated at 80° C.; the kneaded material was then interposed between two sheets of polyethylene terephthalate using a press, thereby fabricating a sealing material 3 composed mainly of EVA and having a thickness of 500 μm. In addition, as for the above-described fluorescent substance composition, one kind composition or a mixture of plural kinds of compositions may be used.

Subsequently, this sealing material 3 was allowed to stand for cooling to room temperature; the polyethylene terephthalate film was released; the resultant was laminated together with a front glass 2, a solar battery cell 4, and a back sheet 5 as shown in FIG. 1; and the laminate was preliminarily press bonded using a vacuum laminator set up at 150° C. The preliminarily press bonded laminate was heated in an oven at 155° C. for 30 minutes and then subjected to crosslinking and adhesion, thereby fabricating a solar battery panel 1. In the present invention, the fluorescent substance whose excitation band is adaptive is used as the wavelength conversion material, the wavelength conversion material having high light conversion efficiency is further used, and the wavelength conversion material is further set up in the direction where the amount of light going toward the solar battery cell is increased. Therefore, the current amount of the solar battery panel was large, and the current amount was increased by 9% as compared with the case of not using the wavelength conversion material.

### EXAMPLE 8

To a transparent resin (EVA), small amounts of an organic peroxide, a crosslinking auxiliary, and an adhesion enhancer were added; a needle acrylic resin (vertical length a=680 μm, horizontal length b=30 μm) having a (Ba,Sr,Ca)₂SiO₄:Eu fluorescent substance (particle diameter: 20 μm) sealed therein was mixed in a proportion of 0.5% by weight; the contents were kneaded using a roll mill heated at 80° C.; the kneaded material was then interposed between two sheets of polyethylene terephthalate using a press, thereby fabricating a sealing material 3 composed mainly of EVA and having thickness of 500 μm. In addition, as for the above-described fluorescent substance composition, one kind composition or a mixture of plural kinds of compositions may be used.

Subsequently, this sealing material 3 was allowed to stand for cooling to room temperature; the polyethylene terephthalate film was released; the resultant was laminated together with a front glass 2, a solar battery cell 4, and a back sheet 5 as shown in FIG. 1; and the laminate was preliminarily press bonded using a vacuum laminator set up at 150° C. The preliminarily press bonded laminate was heated in an oven at 155° C. for 30 minutes and then subjected to crosslinking and adhesion, thereby fabricating a solar battery panel 1. In the present invention, the fluorescent substance whose excitation band is adaptive is used as the wavelength conversion material, the wavelength conversion material having high light conversion efficiency is further used, and the wavelength conversion material is further set up in the direction where the amount of light going toward the solar battery cell is increased. Therefore, the current amount of the solar battery panel was large, and the current amount was increased by 10% as compared with the case of not using the wavelength conversion material.

### EXAMPLE 9

To a transparent resin (EVA), small amounts of an organic peroxide, a crosslinking auxiliary, and an adhesion enhancer were added; a needle acrylic resin (vertical length a=680 μm, horizontal length b=20 μm) having a CaAlSiN₃:Eu fluorescent substance (particle diameter: 15 μm) sealed therein was mixed in a proportion of 0.5% by weight; the contents were kneaded using a roll mill heated at 80° C.; the kneaded material was then interposed between two sheets of polyethylene terephthalate using a press, thereby fabricating a sealing material 3 composed mainly of EVA and having a thickness of 500 μm. In addition, as for the above-described fluorescent substance composition, one kind composition or a mixture of plural kinds of compositions may be used.

Subsequently, this sealing material 3 was allowed to stand for cooling to room temperature; the polyethylene terephthalate film was released; the resultant was laminated together with a front glass 2, a solar battery cell 4, and a back sheet 5 as shown in FIG. 1; and the laminate was preliminarily press bonded using a vacuum laminator set up at 150° C. The preliminarily press bonded laminate was heated in an oven at 155° C. for 30 minutes and then subjected to crosslinking and adhesion, thereby fabricating a solar battery panel 1. In the present invention, the fluorescent substance whose excitation band is adaptive is used as the wavelength conversion material, the wavelength conversion material having high light conversion efficiency is further used, and the wavelength conversion material is further set up in the direction where the amount of light going toward the solar battery cell is increased. Therefore, the current amount of the solar battery panel was large, and the current amount was increased by 9% as compared with the case of not using the wavelength conversion material.

### EXAMPLE 10

The foregoing Examples are concerned with the case of mixing a wavelength conversion material in a sealing material. However, as shown in FIG. 3, the wavelength conversion material 7 can be used upon being incorporated into the antireflection film 6. In that case, in the case where the thickness of the antireflection film 6 is defined as “d”, and the long diameter and the short diameter of the needle fluorescent substance or the needle resin having a fluorescent substance sealed therein as the wavelength conversion material 7 are defined as “a” and “b”, respectively, there is a relation of “a>b”, and more preferably relations of “a>2b” and “a>d”. Furthermore, a relation with the thickness (d) of the antireflection film 6 is more preferably “a>1.34d”.

The same is also applicable to the case where separately from the antireflection film 6, the wavelength conversion film 8 having, as the wavelength conversion material 7, a needle fluorescent substance or a needle resin having a fluorescent substance sealed therein is disposed outside the front glass 2 as shown in FIG. 4. In that case, when the thickness of the wavelength conversion film 8 is defined as “d”, by specifying the wavelength conversion film 8 and the wavelength conversion material 7 in the same relation as that of the above-described case where the wavelength conversion material 7 is incorporated into the antireflection film 6, the conversion efficiency of solar batteries can be enhanced.

### REFERENCE SIGN LIST

1: Solar battery module

2: Front glass

3: Sealing material

4: Solar battery cell

5: Back sheet

6: Antireflection film

7: Wavelength conversion material

8: Wavelength conversion film

9: Condensing lens

10: Supporting frame

11: Substrate

20: Fluorescent substance

30: Needle resin

1-26. (canceled)

27. A solar battery module comprising a solar battery cell and a sealing material sheet that protects the solar battery cell, characterized in that:
the sealing material sheet is mixed with a needle resin having a fluorescent substance sealed therein, and the sealing material sheet has a thickness (c);
when an average long diameter of the needle resin is defined as “a” and an average short diameter of the needle resin is defined as “b”, there are relations of “a>b” and “a>c”;
the fluorescent substance to be sealed in the needle resin is MMgAl₁₀O₁₇:Eu,Mn, wherein M is one kind or plural kinds of elements of Ba, Sr, and Ca; and
the needle resin and the solar battery cell are laminated in this order from the sunlight incident side.

28. The solar battery module according to claim 27, characterized in that:
when an average long diameter of the needle resin is defined as “a” and an average short diameter of the needle resin is defined as “b”, there are relations of “a>2b” and “a>c”.

29. The solar battery module according to claim 27, characterized in that:
when an average long diameter of the needle resin is defined as “a” and a thickness of the sealing material sheet is defined as “c”, there is a relation of “a>1.34c”.

30. The solar battery module used for solar batteries according to claim 27, characterized in that:
the sealing material is composed mainly of an ethylene-vinyl acetate copolymer (EVA).

31. The solar battery module according to claim 30, characterized in that:
the sealing material is any one kind or a mixture of plural kinds of additives of an organic peroxide, a crosslinking auxiliary, and an adhesion enhancer.

32. A solar battery module comprising a front glass having an antireflection film formed on the outside surface thereof and, in the inside of the front glass, a protective sealing material sheet between the front glass and a solar battery cell, characterized in that:
the antireflection film is mixed with a needle resin having a fluorescent substance sealed therein, and the antireflection film has a thickness (c);
when an average long diameter of the needle resin is defined as “a” and an average short diameter of the needle resin is defined as “b”, there are relations of “a>b” and “a>c”;
the fluorescent substance to be sealed in the needle resin is MMgAl₁₀O₁₇:Eu,Mn, wherein M is one kind or plural kinds of elements of Ba, Sr, and Ca; and
the needle resin and the solar battery cell are laminated in this order from the sunlight incident side.

33. A solar battery module comprising a front glass having a wavelength conversion film formed on the outside surface thereof and, in the inside of the front glass, a protective sealing material sheet between the front glass and a solar battery cell, characterized in that:
the wavelength conversion film is mixed with a needle resin having a fluorescent substance sealed therein, and the wavelength conversion film has a thickness (c);
when an average long diameter of the needle resin is defined as “a” and an average short diameter of the needle resin is defined as “b”, there are relations of “a>b” and “a>c”;
the fluorescent substance to be sealed in the needle resin is MMgAl₁₀O₁₇:Eu,Mn, wherein M is one kind or plural kinds of elements of Ba, Sr, and Ca; and
the needle resin and the solar battery cell are laminated in this order from the sunlight incident side.

34. The solar battery module according to claim 27, characterized in that:
a light emitting component from the needle resin is larger in the direction perpendicular to a sunlight incidence plane than in the direction parallel to the sunlight incidence plane.

35. The solar battery module according to claim 32, characterized in that:
a light emitting component from the needle resin is larger in the direction perpendicular to a sunlight incidence plane than in the direction parallel to the sunlight incidence plane.

36. The solar battery module according to claim 33, characterized in that:
a light emitting component from the needle resin is larger in the direction perpendicular to a sunlight incidence plane than in the direction parallel to the sunlight incidence plane.

37. The solar battery module according to claim 27, characterized in that:
an angle formed by a long axis of the needle resin and a direction perpendicular to a sunlight incidence plane is larger than 41.8°.

38. The solar battery module according to claim 32, characterized in that:
an angle formed by a long axis of the needle resin and a direction perpendicular to a sunlight incidence plane is larger than 41.8°.

39. The solar battery module according to claim 33, characterized in that:
an angle formed by a long axis of the needle resin and a direction perpendicular to a sunlight incidence plane is larger than 41.8°.
